(19) United States
(12) Patent Application Publication
(10) Pub. No.: US 2019/0025659 A1
(43) Pub. Date: Jan. 24, 2019

(54) DISPLAY DEVICE

(71) Applicant: Japan Display Inc., Minato-ku (JP)

(72) Inventors: Makoto UCHIDA, Tokyo (JP); Takanori Tsunashima, Tokyo (JP); Hitoshi Tanaka, Tokyo (JP)

(73) Assignee: Japan Display Inc., Minato-ku (JP)

(21) Appl. No.: 16/036,087

(22) Filed: Jul. 16, 2018

(30) Foreign Application Priority Data
Jul. 20, 2017 (JP) 2017-141061

(51) Int. Cl. G02F 1/1362; G02F 1/1335; G02F 1/1343; G02F 1/1337; G02F 1/1333; G02F 1/1345

(52) U.S. Cl. CPC G02F 1/136286; G02F 1/133603; G02F 1/133514; G02F 1/133512; G02F 1/134309; H05K 1/189; G02F 1/133345; G02F 1/1345; G02F 2201/123; G02F 2201/121; G09G 2300/0426; G02F 1/133723

(57) ABSTRACT

According to one embodiment, a display device including a first source line, a second source line and a third source line arranged in a first direction, a first gate line crossing the first source line, a second gate line separated from the first gate line in the first direction and crossing the third source line, a first semiconductor layer including a first crossing portion which crosses the first gate line and is located on a first source line side between the first source line and the second source line, and a second semiconductor layer including a second crossing portion which crosses the second gate line and is located on a third source line side between the second source line and the third source line.

### CROSS-REFERENCE TO RELATED APPLICATIONS

This application is based upon and claims the benefit of priority from Japanese Patent Application No. 2017-141061, filed Jul. 20, 2017, the entire contents of which are incorporated herein by reference.

### FIELD

Embodiments described herein relate generally to a display device.

### BACKGROUND

Recently, along with the prevalence of virtual reality (VR), ultra-high-definition display devices have been in demand to realize more realistic display. In a conventional structure, a display device comprises two integrated circuits (ICs). The two integrated circuits drive two areas formed in such a manner as to divide gate lines arranged in a display panel, respectively. The size of pixels or the distance between two adjacent pixels on the boundary between the two areas may become greater than the size of pixels or the distance between two adjacent pixels in the area other than the boundary in some cases.

### BRIEF DESCRIPTION OF THE DRAWINGS

FIG. 1 is a perspective view showing an example of the external appearance of a liquid crystal display device.

FIG. 2 is a plan view schematically showing a first substrate according to an embodiment.

FIG. 3 is a plan view schematically showing a second substrate according to the embodiment.

FIG. 4 is a sectional view of a display panel taken along line A-A.

FIG. 5 is a plan view schematically showing a first substrate according to another example of the structure of the display device of the embodiment.

FIG. 6 is a plan view schematically showing a first substrate according to another example of the structure of the display device of the embodiment.

FIG. 7 is a plan view schematically showing a first substrate according to another example of the structure of the display device of the embodiment.

### DETAILED DESCRIPTION

In general, according to one embodiment, a display device comprises: a first source line, a second source line and a third source line arranged in a first direction; a first gate line extending in the first direction and crossing the first source line; a second gate line extending in the first direction, separated from the first gate line in the first direction, and crossing the third source line; a first semiconductor layer comprising a first crossing portion which crosses the first gate line and is located on a first source line side between the first source line and the second source line; and a second semiconductor layer comprising a second crossing portion which crosses the second gate line and is located on a third source line side between the second source line and the third source line.

According to another embodiment, a display device comprises: a first source line, a second source line and a third source line arranged at regular intervals in a first direction; a first gate line extending in the first direction and crossing the first source line; a second gate line extending in the first direction, separated from the first gate line in the first direction, and crossing the third source line; a first semiconductor layer comprising a first crossing portion which crosses the first gate line and is located between the first source line and the second source line; and a second semiconductor layer comprising a second crossing portion which crosses the second gate line and is located between the second source line and the third source line.

An embodiment will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated in the drawings schematically, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the present embodiment, a display device will be disclosed as an example of an electronic device. The display device can be used in various devices such as virtual reality (VR) viewers, smartphones, tablet computers, mobile phones, notebook computers and game consoles.

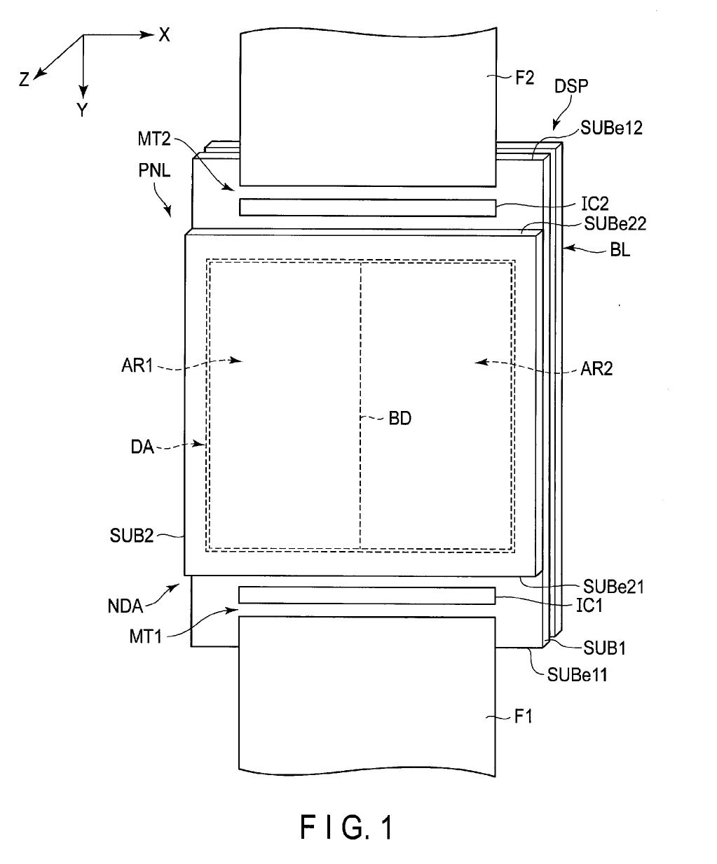

FIG. 1 is a perspective view showing an example of the external appearance of a liquid crystal display device DSP. A first direction X, a second direction Y and a third direction Z orthogonally cross each other but may cross each other at an angle other than an angle of 90 degrees. The first direction X and the second direction Y correspond to directions parallel to the main surfaces of substrates which constitute the liquid crystal display device (hereinafter referred to simply as a display device) DSP, and the third direction Z correspond to the thickness direction of the display device DSP. In the following, the direction of the pointing end of an arrow indicating the third direction Z is defined as above, and the opposite direction to the pointing end of the arrow is defined as below. Further, the figure shows a plan view of the display device DSP in an X-Y plane defined by the first direction X and the second direction Y. A view of the X-Y plane in the third direction Z is referred to as a plan view in the following description. In some cases, the direction of the pointing end of an arrow indicating the first direction X may be referred to as right, and the opposite direction to the pointing end of the arrow may be referred to as left.

The display device DSP includes a display panel PNL and an illumination device BL.

The display panel PNL includes a first substrate SUB1, a second substrate SUB2 and a liquid crystal layer (liquid crystal layer LC which will be described later) held between the first substrate SUB1 and the second substrate SUB2. Further, the display panel PNL includes a display area DA and a non-display area NDA. The display area DA is an area in which an image is displayed. The display area DA is located at substantially the center of an area in which the first substrate SUB1 and the second substrate SUB2 are opposed to each other. Further, the display area DA is divided into a first area AR1 and a second area AR2. For example, a boundary BD between the first area AR1 and the second area AR2 are located at the center of the width of the display area DA in the first direction X. In the following, the boundary BD may indicate a border line between the first area AD1 and the second area AR2 in some cases and may include a peripheral area of the border line in other cases. The non-display area NDA is an area in which an image is not displayed, and is located outside the display area DA.

The first substrate SUB1 has a first mounting portion MT1 extending outward beyond a substrate side edge SUBe21 of the second substrate SUB2, and a second mounting portion MT2 extending outward beyond a substrate side edge SUBe22 of the second substrate SUB2. The first mounting portion MT1 is formed along a substrate side edge SUBe11 of the first substrate SUB1. The second mounting portion MT2 is formed along a substrate side edge SUBe12 which is opposed to the substrate side edge SUBe11 of the first substrate SUB1 in the second direction Y. In the example illustrated, the substrate side edges SUBe11, SUBe12, SUBe21 and SUBe22 extend in the first direction X. The substrate side edges SUBe11 and SUBe21 are substantially parallel to each other. Further, the substrate side edges SUBe12 and SUBe22 are substantially parallel to each other. The first substrate SUB1 may have one of the first mounting portion MT1 and the second mounting portion MT2 instead.

Signal supply sources necessary for the display panel such as IC chips IC1 and IC2 and flexible printed circuit (FPC) boards F1 and F2 are located in the non-display area NDA. In the example illustrated, the IC chip IC1 and the FPC board F1 are mounted on the first mounting portion MT1 of the first substrate SUB1. The IC chip IC2 and the FPC board F2 are mounted on the second mounting portion MT2 of the first substrate SUB1. The IC chips IC1 and IC2 and the FPC boards F1 and F2 may be mounted on one of the first mounting portion MT1 and the second mounting portion MT2. For example, the IC chips IC1 and 102 and the FPC boards F1 and F2 may be mounted on the first mounting portion MT1. Although not shown in the drawing, connection terminals which connect signal supply sources are provided in the first mounting portion MT1 and the second mounting portion MT2, respectively. The connection terminals may be electrically connected to source lines and gate lines which will be described later.

The illumination device BL is arranged on a rear surface side (opposite side to a surface opposed to the second substrate SUB2) of the first substrate SUB1 in the third direction Z. Various types of illumination device can be adopted as the illumination device BL. For example, the illumination device BL includes a light guide opposed to the first substrate SUB1, a plurality of light sources such as light-emitting diodes (LEDs) arranged along an end of the light guide, a reflective sheet arranged on one main surface side of the light guide, various optical sheets stacked on the other main surface side of the light guide, etc.

The display panel PNL of the example illustrated is a transmissive display panel which displays an image by selectively transmitting light emitted from the illumination device BL but is not limited to this. For example, the display panel PNL may be a reflective display panel which displays an image by selectively reflecting external light or light emitted from an external light source, or may be a transflective display panel which has both the function of a transmissive display panel and the function of a reflective display panel.

Further, although the detailed structure of the display panel PNL will not be described here, the display panel PNL can adopt any of a display mode which uses a longitudinal electric field along the normal to the display panel PNL, a display mode which uses an inclined electric field inclined with respect to the normal to the display panel PNL, and a display mode which uses a lateral electric field along the main surfaces of the display panel PNL.

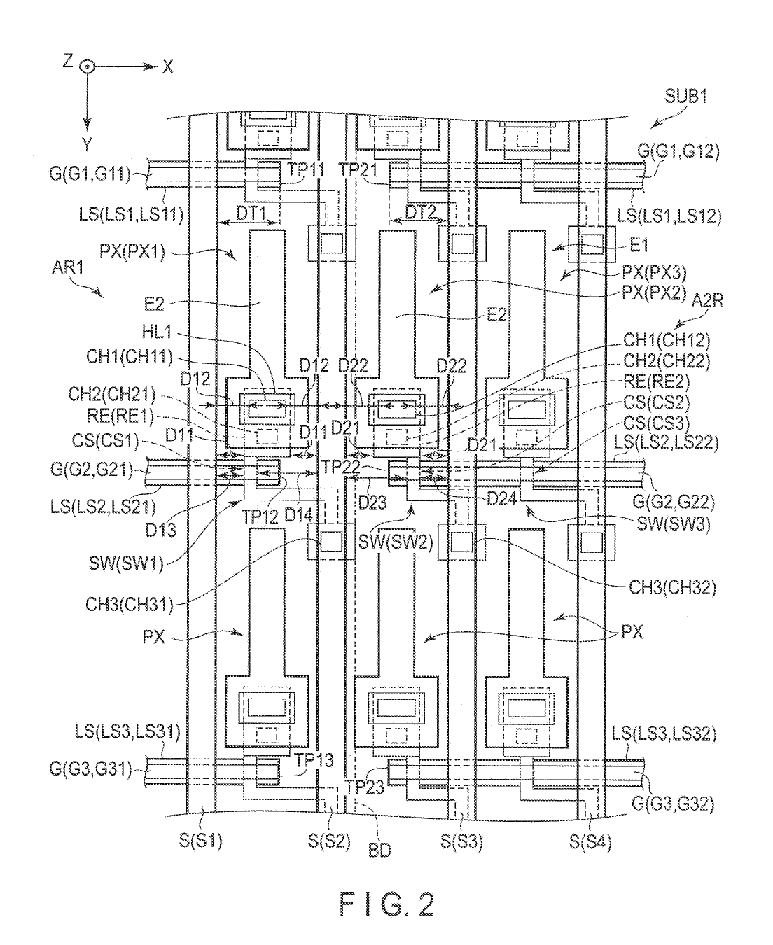

FIG. 2 is a plan view schematically showing the first substrate SUB1 according to the present embodiment. FIG. 2 shows the boundary BD of the first substrate SUB1. Here, an example of the structure adopting a fringe field switching (FFS) mode which is one of display modes using a lateral electric field will be described.

The first substrate SUB1 includes a plurality of source lines S (S1, S2, S3, S4 . . . ), a plurality of gate lines G (G1, G2, G3 . . . ), a plurality of light-shielding layers LS (LS1, LS2, LS3 . . . ), a first electrode E1, a second electrode E2, a relay electrode RE (RE1, RE2 . . . ) a switching element SW (SW1, SW2 . . . ). FIG. 2 only shows structures necessary for explanation.

The source lines S (S1, S2, S3, S4 . . . ) are arranged at predetermined intervals in the first direction X. In the example illustrated, the source lines S1 to S4 are arranged at regular intervals in the first direction X. The source lines S (S1, S2, S3, S4 . . . ) extend in the second direction Y. Further, the source line S2 is located on the boundary BD between the first area AR1 and the second area AR2. The source lines S (S1, S2, S3, S4 . . . ) may be partially crooked. The source lines S (S1, S2, S3, S4 . . . ) are formed of, for example, a three-layer film of titanium, aluminum and titanium, a three-layer film of aluminum, titanium and aluminum, etc.

The gate lines G (G1, G2, G3 . . . ) are arranged at predetermined intervals in the second direction Y. The gate lines G (G1, G2, G3 . . . ) extend in the first direction X and are divided on the boundary BD. In the example illustrated, the gate line G1 is divided into a gate line G11 and a gate line G12 on the boundary BD. The gate line G2 is divided into a gate line G21 and a gate line G22 on the boundary BD. The gate line G3 is divided into a gate line G31 and a gate line G32 on the boundary BD. In other words, the gate line G11 and the gate line G12 are in line with each other and are separated from each other in the first direction X. The gate line G21 and the gate line G22 are in line with each other and are separated from each other in the first direction X. The gate line G31 and the gate line G32 are in line with each other and are separated from each other in the first direction X. The gate line G11 and the gate line G12 are assumed to be in line with each other but may be deviated from each other in the second direction Y. Similarly, the gate line G21 and the gate line G22 may be deviated from each other in the second direction Y. The gate line G31 and the gate line G32 may be deviated from each other in the second direction Y.

The gate lines G11, G12, G21, G22, G31 and G32 do not overlap the source line S2. In the example illustrated, the gate lines G11, G21 and G31 are separated from the source line S2 to the left side. The gate lines G12, G22 and G32 are separated from the source line S2 to the right side. For example, the gate line G11 extends in the first direction X from the source line S1 to the source line S2 and does not overlap the source line S2. An end TP11 of the gate line G11 is located at a distance DT1 from the source line S1 to the right side. The distance DT1 is less than the distance between the source line S1 and the source line S2 in the first direction X. The gate line G21 and the gate line G31 also extend in the first direction X from the source line S1 to the source line S2 and does not overlap the source line S2. An end TP12 of the gate line G21 and an end TP13 of the gate line G31 are also arranged at the same distance as that of the end TP11 from the source line S1 to the right side. The ends TP11 to TP13 may be arranged at different distances from the source line S1 to the right side. Further, the gate line G12 extends in the first direction X from the source line S3 to the source line S2 and does not overlap the source line S2. An end TP21 of the gate line G12 is located at a distance DT2 from the source line S3 to the left side. The distance DT2 is less than the distance between the source line S2 and the source line S3 in the first direction X. The gate line G22 and the gate line G32 also extend in the first direction X from the source line S3 to the source line S2 and overlaps the source line S2. An end TP22 of the gate line G22 and an end TP32 of the gate line G32 are arranged at the same distance as that of the end TP21 from the source line S3 to the left side. The ends TP21 to TP23 may be arranged at different stances from the source line S3 to the left side. For example, the distance DT1 may be the same as the distance DT2. The gate lines G (G1, G2, G3 . . . ) may be partially crooked. The gate lines G (G1, G2, G3 . . . ) may be formed of, for example, a molybdenum tungsten alloy film.

Further, the gate lines G cross the source lines S. In the drawing, the pixel PX corresponds to an area defined by two adjacent gate lines and two adjacent source lines. For example, the pixel PX corresponds to an area defined by the gate lines G1 and G2 and the source lines S1 and S2.

The light-shielding layers LS (LS1, LS2, LS3 . . . ) are arranged at predetermined intervals in the second direction Y. The light-shielding layers LS (LS1, LS2, LS3 . . . ) overlap the gate lines G (G1, G2, G3 . . . ), respectively, and extend in the first direction X along the gate lines G. In the example illustrated, the light-shielding layer LS1 is divided into a light-shielding layer LS11 and a light-shielding layer LS12 on the boundary BD. The light-shielding layer LS2 is divided into a light-shielding layer LS21 and a light-shielding layer LS22 on the boundary BD. The light-shielding layer LS3 is divided into a light-shielding layer LS31 and a light-shielding layer LS32 on the boundary BD. In other words, the light-shielding layer LS11 and the light-shielding layer LS12 are in line with each other and are separated from each other in the first direction X. The light-shielding layer LS21 and the light-shielding layer LS22 are in line with each other and are separated from each other in the first direction X. The light-shielding layer LS31 and the light-shielding layer LS32 are in line with each other and are separated from each other in the first direction X. The light-shielding layer LS11 and the light-shielding layer LS12 are assumed to be in line with each other but may be deviated from each other in the second direction Y. Similarly, the light-shielding layer LS21 and the light-shielding layer LS22 may be deviated from each other in the second direction Y. The light-shielding layer LS31 and the light-shielding layer LS32 may be deviated from each other in the second direction Y.

The light-shielding layers LS11, LS12, LS21, LS22, LS31 and LS32 do not overlap the source line S2. In the example illustrated, the light-shielding layer LS11, LS21 and LS31 are separated from the source line S2 to the left side in the first direction X. The light-shielding layers LS12, LS22 and LS32 are separated from the source line S2 to the right side in the first direction X. The light-shielding layers LS (LS1, LS2, LS3 . . . ) may be partially crooked. Further, the light-shielding layer LS may be divided in an island-like manner in the first direction X. For example, the light-shielding layer LS may be formed in an island shape at a position overlapping a crossing portion CS of the switching element SW which will be described later. Further, the light-shielding layer LS may not be divided. For example, the light-shielding layer LS may extend in the first direction X and may be linearly formed. The light-shielding layers LS are formed of a molybdenum tungsten alloy, for example. In the example illustrated, the width of the light-shielding layer LS in the second direction Y is greater than the width of the gate line G in the second direction Y.

The first electrode E1 is arranged across the pixels PX. In the example illustrated, the first electrode E1 extends in the first direction X and the second direction Y in the X-Y plane. In a plan view, the first electrode E1 overlaps the source line S, the gate line G, the light-shielding layer LS, the second electrode E2, etc. The first electrode E1 has a plurality of openings HL1 located in the respective pixels PX.

The second electrode E2 is a pixel electrode arranged in each pixel PX. A potential corresponding to a video signal is applied to the second electrode E2. In the example illustrated, the second electrode E2 has the shape of a flat plate having a projection extending in the second direction Y from one side of a rectangle, and extends substantially parallel to the source line S. The second electrode E2 is assumed to have the shape of a flat plate having a projecting extending in the second direction Y from one side of a rectangle, but may have a shape having a slit or another shape.

The relay electrode RE is electrically connected to the second electrode E2. In the example illustrated, the relay electrode RE is connected to the second electrode E2 via a contact hole CH1. For example, the relay electrode RE1 is connected to the second electrode E2 via a contact hole CH11. The relay electrode RE2 is connected to the second electrode E2 via a contact hole CH12. In the example illustrated, the relay electrode RE is located at substantially the center between two adjacent source lines S. For example, the relay electrode RE1 is located at a distance D11 from the source line S1 to the right side and is located at the distance D11 from the source line S2 to the left side. Further, the relay electrode RE2 is located at a distance D21 from the source line S2 to the right side and is located at the distance D21 from the source line S3 to the left side. The relay electrode RE is formed of, for example, a three-layer film of titanium, aluminum and titanium stacked in order, a three-layer film of aluminum, titanium and aluminum stacked in order, etc.

The contact hole CH1 is located at substantially the center between two adjacent source lines inside the opening HL1. For example, the contact hole CH1 is located at substantially the center between two adjacent source lines S. In the example illustrated, the contact hole CH11 is located at a distance D12 from the source line S1 to the right side and is located at the distance D12 from the source line S2 to the left side. The contact hole CH12 is located at a distance D22 from the source line S2 to the right side and is located at the distance D22 from the source line S3 to the left side.

The switching element SW is electrically connected to the source line S and the gate line G. That is, the switching element SW is electrically connected to the second electrode E2 via the relay electrode RE. In the example illustrated, one end of the switching element SW is connected to the relay electrode RE via a contact hole CH2, and the other end of the switching element SW is connected to the source line S via a contact hole CH3. For example, one end of the switching element SW1 is connected to the relay electrode RE1 via a contact hole CH21, and the other end of the switching element SW1 is connected to the source line S2 via a contact hole CH31. One end of the switching element SW2 is connected to the relay electrode RE2 via a contact hole CH22, and the other end of the switching element SW2 is connected to the source line S3 via a contact hole CH32.

The switching element SW crosses the gate line G between one end connected to the relay electrode RE and the other end connected to the source line S. A portion of the switching element SW crossing the gate line G is referred to as a crossing portion CS.

In the example illustrated, the switching element SW in each pixel PX has one crossing portion CS. In the pixel PX located on the boundary BD, the crossing portion CS is displaced toward one of two adjacent source lines S between these two source lines S. For example, the switching element SW1 has a crossing portion CS1 in a pixel PX1 on the boundary BD. The crossing portion CS1 crosses the gate line G21 and is located on the source line S1 side between the source line S1 and the source line S2. For example, the crossing portion CS1 is located at a distance D13 from the source line S1 to the right side and is located at a distance D14 from the source line S2 to the left side. The distance D14 is greater than the distance D13. The crossing portion CS1 may be located on the source line S1 side from the contact hole CH11 between the source line S1 and the source line S2. In a pixel PX2 on the boundary BD, the switching element SW2 has a crossing portion CS2. The crossing portion CS2 crosses the gate line G22 and is located on the source line S3 side between the source line S2 and the source line S3. For example, the crossing portion CS2 is located at a distance D23 from the source line S2 to the right side and is located at a distance D24 from the source line S3 to the left side. The distance D23 is greater than the distance D24. The crossing portion CS2 may be located on the source line S3 side from the contact hole CH11 between the source line S2 and the source line S3. Further, in the area other than the boundary, the crossing portion CS is located at substantially the center between two adjacent source lines S. For example, a switching element SW3 has a crossing portion CS3 in a pixel PX3. The crossing portion CS3 crosses the gate line G22 and is located at substantially the center between the source line S3 and the source line S4. In each pixel PX, the switching element SW is assumed to have one crossing portion CS but may have two or more crossing portions CS.

The crossing portion CS crosses the light-shielding layer LS. For example, the crossing portion CS1 crosses the light-shielding layer LS21 in the pixel PX1. The crossing portion CS2 crosses the light-shielding layer LS22 in the pixel PX2. The crossing portion CS3 crosses the light-shielding layer LS22 in the pixel PX2.

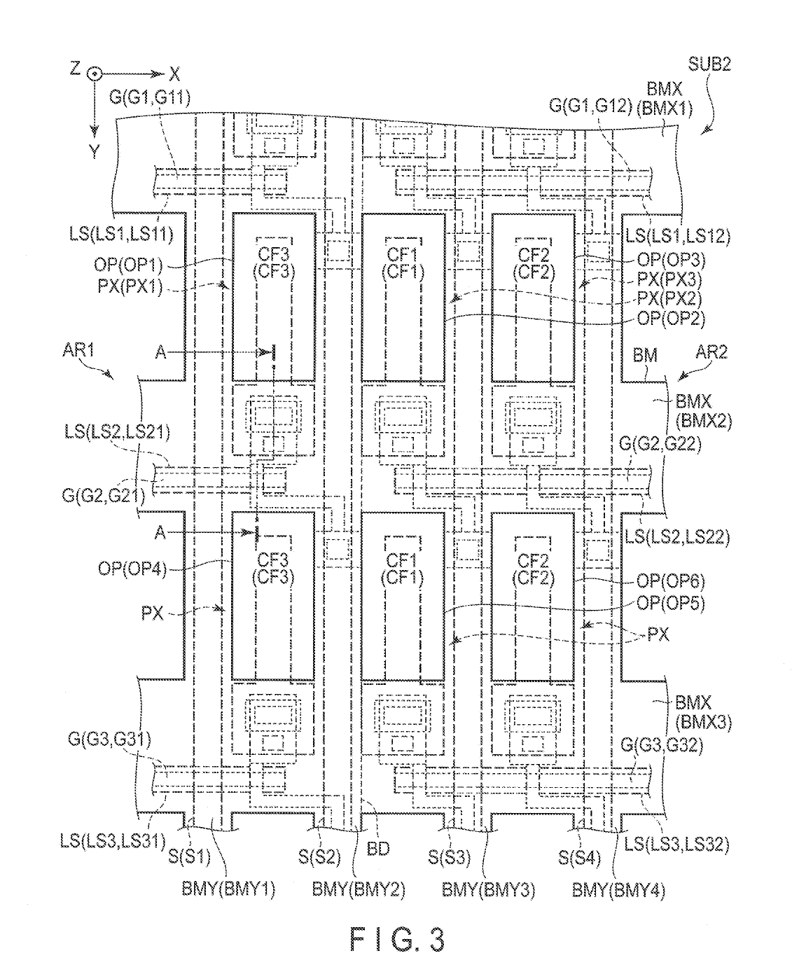

FIG. 3 is a plan view schematically showing the second substrate SUB2 according to the present embodiment. FIG. 3 only shows structures necessary for explanation. Further, FIG. 3 shows the main portions of the first substrate SUB1 of FIG. 2 by dashed lines.

The second substrate SUB2 includes a light-shielding layer BM and a color filter CF.

The light-shielding layer BM has light-shielding characteristics. In the example illustrated, the light-shielding layer BM has the shape of a grid. The light-shielding layer BM may have the shape of a ladder, a strip, etc., instead of the shape of a grid. For example, the light-shielding layer BM includes longitudinal portions BMY and lateral portions BMX. The longitudinal portions BMY are arranged at intervals in the first direction X and extend in the second direction Y. In a plan view, the longitudinal portion BMY overlaps the source line S. The longitudinal portion BMY has the shape of a strip having a substantially constant width in the first direction X. In the example illustrated, longitudinal portions BMY1, BMY2, BMY3 and BMY4 have substantially the same width in the first direction X and are arranged at regular intervals in the first direction X. The longitudinal portions BMY1 to BMY4 extend in the second direction Y along the source lines S1 to S4 and overlap the source lines S1 to S4, respectively. The longitudinal portions BMX are arranged at intervals in the second direction Y and extend in the first direction X. In a plan view, the lateral portion BMX overlaps the gate line G, the light-shielding layer LS and the wiring line of the switching element SW, etc. The lateral portion BMX has the shape of a strip having a substantially constant width in the second direction Y. In the example illustrated, lateral portions BMX1, BMX2 and BMX3 have substantially the same width in the second direction Y and are arranged at regular intervals in the second direction Y. The lateral portions BMX1 to BMX3 extend along the gate lines G1 to G3 and overlap the gate lines G1 to G3, respectively. In a plan view, the lateral portion BMY and the lateral portion BMX cross each other. In the example illustrated, the longitudinal portion BMY and the lateral portion BMX cross each other in shape of a cross. The longitudinal portion BMY and the lateral portion BMX may cross each other in the shape of the latter T or letter Y instead.

An opening OP is an area which is defined by the light-shielding layer BM and contributes to display. The openings OP are arranged in a matrix in the X-Y plane. In the example illustrated, openings OP1, OP2, OP3, OP4, OP5 and OP6 are arranged in a matrix. The openings OP1 to OP6 have substantially the same size.

The color filter CF overlaps the opening OP. The color filter CF includes a color filter CF1 of the first color, a color filter CF2 of the second color, and a color filter CF3 of the third color. The first color, the second color and the third color are different colors. For example, the color filter CF1 is a red color filter, the color filter CF2 is a green color filter, and the color filter CF3 is a blue color filter. The combination of the colors of the color filters CF1 to CF3 is not limited to that of the previously-described example. The color filter CF may further include a white color filter.

The color filters CF1 to CF3 are arranged in order in the first direction X. Further, the color filters CF1 to CF3 are arranged in the second direction Y. In the example illustrated, the color filter CF3 overlaps the openings OP1 and OP4. The color filter CF1 overlaps the openings OP2 and OP5. The color filter CF2 overlaps the openings OP3 and OP6.

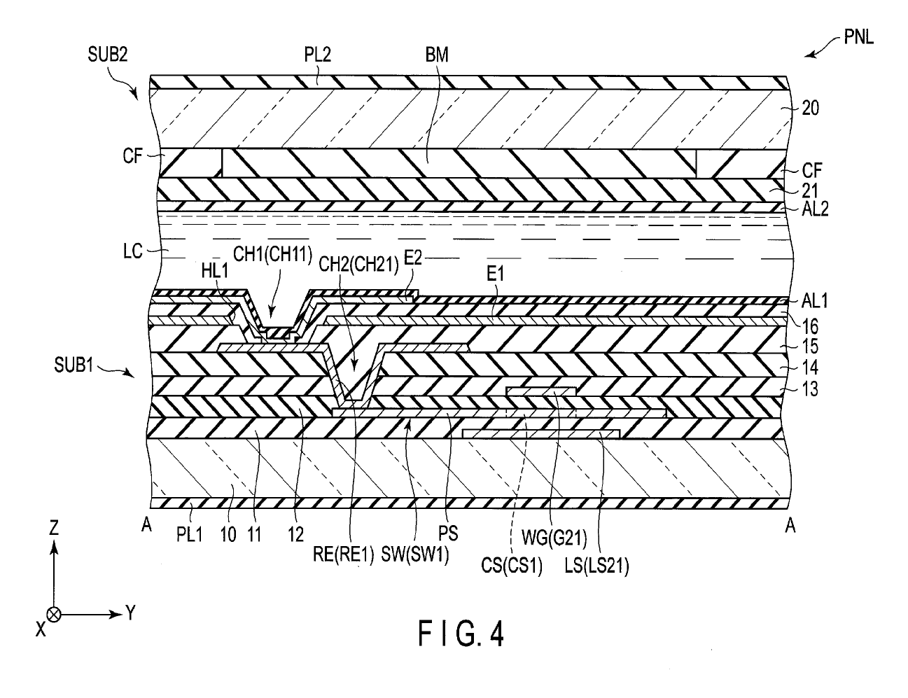

FIG. 4 is a sectional view of the display panel PNL taken along line A-A of FIG. 3.

The first substrate SUB1 includes a support substrate 10, insulating films 11, 12, 13, 14, 15 and 16, the light-shielding layer LS, the switching element SW, the relay electrode RE, the first electrode E1, the second electrode E2, and an alignment film AL1, etc. A polarizer PL1 is provided below the support substrate 10. The insulating films 11 to 16 may be expressed as interlayer insulating films in some cases.

The support substrate 10 is transparent and is formed of glass such as borosilicate glass, for example, but may be formed of resin such as plastic.

The insulating films 11 to 16 are all transparent. The insulating films 11 to 14 and 16 are inorganic insulating films and are formed of, for example, silicon nitride or silicon oxide. The insulating film 15 is an organic insulating film and is formed of, for example, resin such as acrylic resin. The light-shielding layer LS (LS21) is located on the support substrate 10 and contacts the support substrate 10. The light-shielding layer LS (LS21) is formed of, for example, a molybdenum tungsten alloy. The insulating film 11 is located on the light-shielding layer LS (LS21) and the support substrate 10 and contacts the support substrate 10 and the light-shielding layer LS (LS21). The switching element SW (SW1) includes a semiconductor layer PS. The semiconductor layer PS is located on the insulating film 11 and contacts the insulating film 11. The semiconductor layer PS is, for example, a polycrystalline silicon or oxide semiconductor layer. The insulating film 12 is located on the insulating film 11 and the semiconductor layer PS and contacts the insulating film 11 and the semiconductor layer PS. A gate electrode WG which is a part of the gate line G (G21) is located on the insulating film 12 and contacts the insulating film 12. The insulating film 13 is located on the insulating film 12 and the gate electrode WG and contacts the insulating film 12 and the gate electrode WG. The insulating film 14 is located on the insulating film 13 and contacts the insulating film 13. The insulating film 11 to the insulating film 14 may be referred to collectively as an insulating film (first insulating film) IL1 in some cases.

The relay electrode RE is located on the insulating film 14 and contacts the insulating film 14. Further, the relay electrode RE contacts the semiconductor layer PS via the contact hole CH2 (CH21) which penetrates the insulating films 12 to 14. The insulating film 15 is located on the insulating film 14 and the relay electrode RE (RE1) and contacts the insulating film 14 and the relay electrode RE (RE1). The first electrode E1 is located on the fifth insulating film 15 and contacts the insulating film 15. The first electrode E1 extends across the pixels PX, in other words, the second electrodes E2. The first electrode E1 has an opening for electrically connecting the second electrode E2 and the switching element SW via the relay electrode RE. For example, the first electrode E1 is a common electrode to which a common potential is applied. The first electrode E1 is formed of, for example, a transparent conductive material such as indium tin oxide (ITO), indium zinc oxide (IZO) or indium gallium oxide (IGO). The first electrode E1 only has to have a transparent portion at a position overlapping an area contributing to display, and the other portion may be formed of a nontransparent material. The insulating film 16 is located on the first electrode E1 and contacts the first electrode E1. The second electrode E2 contacts the relay electrode RE (RE1) via the contact hole CH1 (CH11) which penetrates the insulating film 15 and the insulating film 16. Further, the gate electrode WG and the light-shielding layer SL2 should preferably be electrically connected to each other and be at the same potential. The alignment film AL1 covers the insulating film 16 and the second electrode E2. The alignment film AL1 is, for example, a polyimide film.

The liquid crystal layer LC is located on the first substrate SUB1. The liquid crystal layer LC may be a positive liquid crystal layer having positive dielectric anisotropy or may be a negative liquid crystal layer having negative dielectric anisotropy.

The second substrate SUB2 is located on the liquid crystal layer LC. The second substrate SUB2 includes a support substrate 20, the light-shielding layer BM, the color filter CF, an insulating film 21, an alignment film AL2, etc.

A polarizer PL2 is provided above the support substrate 20. The absorption axis of the polarizer PL1 and the absorption axis of the polarizer PL2 are orthogonal to each other in a plan view.

The support substrate 20 is transparent and is formed of glass such as borosilicate glass, for example, but may be formed of resin such as plastic. The light-shielding layer BM is located below the support substrate 20 and contacts the support substrate 20. The light-shielding layer BM overlaps from the contact hole CH1 to the switching element SW (SW1). The color filter CF is located below the support substrate 20 and contacts the support substrate 20. In the example illustrated, the color filter CF is adjacent to the light-shielding layer BM in the second direction Y. The insulating film 21 is located below the light-shielding layer BM and the color filter CF and contacts the light-shielding layer BM and the color filter CF. The color filter CF may be arranged in the first substrate SUB1 instead. The color filter CF may include color filters of four or more colors. In a pixel which displays white, a white color filter or an uncolored resin material may be arranged, or an overcoat layer OC may be arranged without any color filter. The insulating film 21 is a transparent organic insulating film and is formed of, for example, resin such as acrylic resin. The alignment film AL2 is located below the insulating film 21, contacts the insulating film 21 and covers the insulating film 21. The alignment film AL2 is a polyimide optical alignment film.

According to the present embodiment, the display device DSP includes the source lines S and the gate lines G. The source lines S are arranged at regular intervals in the first direction X, for example. The gate lines G are arranged at regular intervals in the second direction Y, for example. The source lines S and the gate lines G cross each other. The gate lines G are divided on the boundary BD. In each pixel PX, the switching element SW has the crossing portion CS which crosses the gate line G. In the pixel PX on the boundary BD, the crossing portion CS is displaced toward one of two adjacent source lines S between these two source lines S. Therefore, in the display device DSP, even if the gate lines G are divided, the size of the pixel PX located on the boundary BD and the size of the pixel PX located in the area other than the boundary BD can be substantially the same as each other. Further, in the display device DSP, the distance between two adjacent pixels PX on the boundary BD and the distance between two adjacent pixels PX in the area other than the boundary BD can be substantially the same as each other. Therefore, the display device DSP which can suppress the degradation of display quality can be provided.

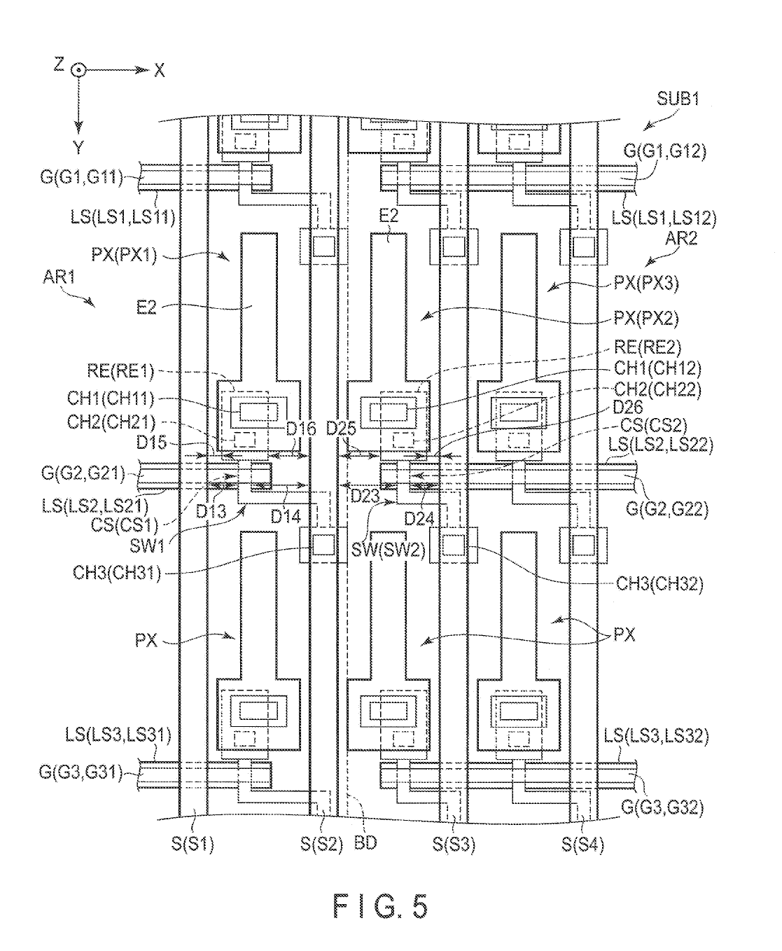

Next, other examples of the structure of the present embodiment will be described with reference to FIGS. 5, 6 and 7. In the other examples of the structure of the present embodiment which will be described below, the same portions as those of the previously-described embodiment will be denoted by the same reference numbers and detailed description thereof will be omitted, and portions different from those of the previously-described embodiment will be mainly described. The same advantages as those of the previously-described embodiment can also be obtained from the other examples.

The structural example shown in FIG. 5 differs from the structural example shown in FIG. 2 in that the relay electrode RE in the pixel PX on the boundary BD is displaced from the center between two adjacent source lines S.

In the example illustrated, the relay electrode RE1 is located on the source line S1 side between the source line S1 and the source line S2. For example, the relay electrode RE1 is located at a distance D15 from the source line S1 to the right side and is located at a distance D16 from the source line S2 to the left side. The distance D16 is greater than the distance D15. The distance D16 may be less than the distance D15. The relay electrode RE1 may be located on the source line S1 side from the contact hole CH11 between the source line S1 and the source line S2. The relay electrode RE2 is located on the source line S3 side between the source line S2 and the source line S3. For example, the relay electrode RE2 is located at a distance D25 from the source line S2 to the right side and is located at a distance D26 from the source line S3 to the left side. The distance D25 is greater than the distance D26. The distance D25 may be less than the distance D26. Further, the relay electrode RE2 may be located on the source line S3 side from the contact hole CH12 between the source line S2 and the source line S3. The same advantages can also be obtained from this structural example.

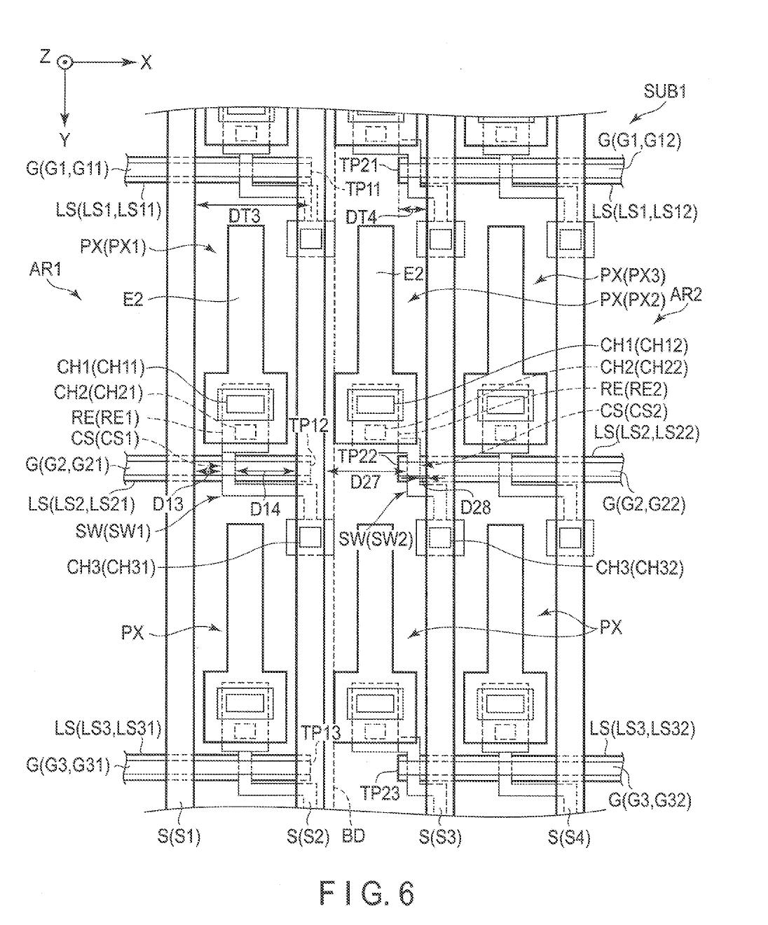

The structural example shown in FIG. 6 differs from the structural example shown in FIG. 2 in that the gate line G overlaps the source line S located on the boundary BD.

In the example illustrated, the gate lines G11, G21 and G31 overlap the source line S2. The gate lines G12, G22 and G32 do not overlap the source line S2. The gate lines G12, G22 and G32 are separated from the source line S2 to the right side. For example, the end TP11 of the gate line G11 is located at a distance DT3 from the source line S1 to the right side and overlaps the source line S2. The end TP12 of the gate line G21 and the end TP13 of the gate line G31 are also located at the same distance as that of the end TP11 from the source line S1 to the right side and overlap the source line S2. The distance DT3 is greater than the distance between the source line S1 and the source line S2 in the first direction X. Further, the end TP21 of the gate line G12 is located at a distance DT4 from the source line S3 to the left side. The end TP22 of the gate line G22 and the end TP32 of the gate line G32 are also located at the same distance as that of the end TP21 from the source line S3 to the left side. The distance DT3 is greater than the distance DT4. The distance DT4 is greater than the distance between the source line S2 and the source line S3 in the first direction X. For example, the distance DT3 may be greater than the distance DT1 and the distance DT2, and the distance DT4 may be less than the distance DT1 and the distance DT2. The gate lines G11, G21 and G31 may not overlap the source line S2, and the gate lines G12, G22 and G32 may overlap the source line S2. Alternatively, the gate lines G11, G12, G21, G22, G31 and G32 may alternately overlap the source line S2. For example, the gate lines G11, G22 and G31 may not overlap the source line S2, and the gate lines G12, G21 and G32 may overlap the source line S2.

In the example illustrated, the light-shielding layers LS11, LS21 and LS31 overlap the source line S2. The light-shielding layer LS12, LS22 and LS32 do not overlap the source line S2. In the example illustrated, the light-shielding layers LS12, LS22 and LS32 are separated from the source line S2 to the right side.

In the example illustrated, the crossing portion CS2 is located at a distance D27 from the source line S2 to the right side and is located at a distance D28 from the source line S3 to the left side. The distance D27 is greater than the distance D28. The distance D27 is, for example, greater than the distance D23. For example, the distance D27 is greater than a half of the distance between the source line S2 and the source line S3. In this case, the crossing portion CS1 may be located at the center between the source line S1 and the source line S2 or may be located on the source line S2 side between the source line S1 and the source line S2. The same advantages can also be obtained from this structural example.

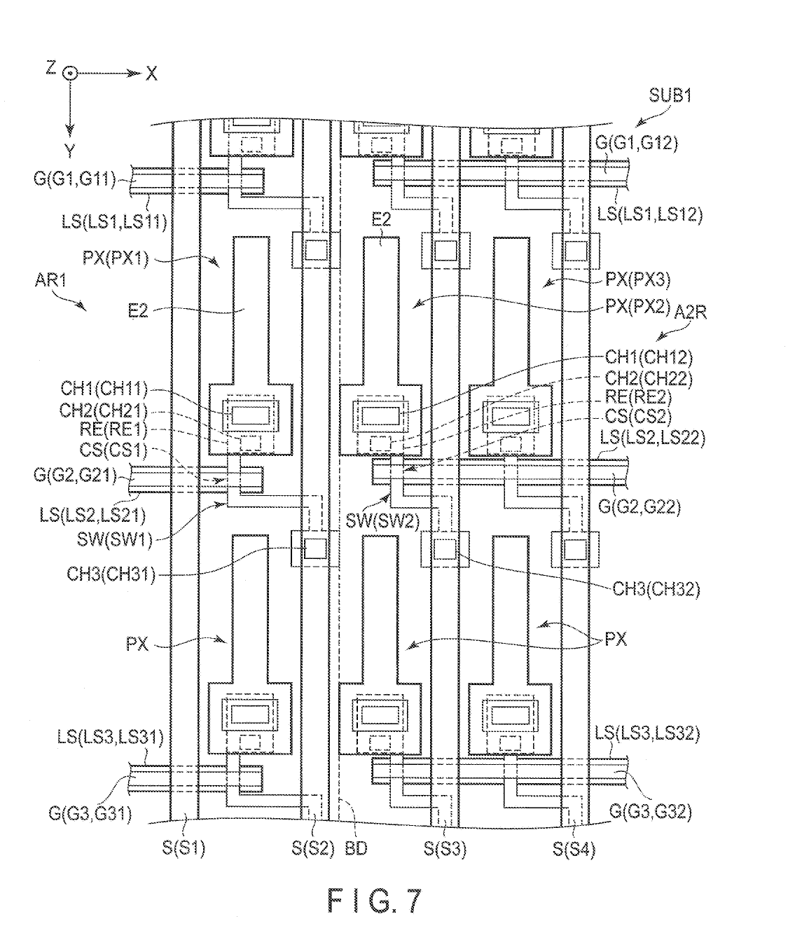

The structural example shown in FIG. 7 differs from the structural example shown in FIG. 2 in that the divided gate lines G are deviated from each other in the second direction Y.

The gate line G may be deviated in the second direction Y within such a range that an area of the gate line G which overlaps the switching element SW does not change. In the example illustrated, the gate lines G11 and G12 overlap the switching elements SW in a range in which the switching elements SW extend in the second direction Y. The gate line G11 is separated from the gate line G12 in the first direction X and is deviated from the gate line G12 in the second direction Y. The gate lines G21 and G22 overlap the switching elements SW in a range in which the switching elements SW extend in the second direction Y. The gate line G21 is separated from the gate line G22 in the first direction X and is deviated from the gate line G22 in the second direction Y. The gate lines G31 and G32 overlap the switching elements SW in a range in which the switching elements SW extend in the second direction Y. The gate line G31 is separated from the gate line G32 in the first direction X and is deviated from the gate line G32 in the second direction Y. Even if two divided gate lines G are deviated from each other in a range in which the switching elements SW extend in the second direction Y, these two gate lines G are assumed to be in line with each other. The same advantages can also be obtained from this structural example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a first source line, a second source line and a third source line arranged in a first direction;
a first gate line extending in the first direction and crossing the first source line;
a second gate line extending in the first direction, separated from the first gate line in the first direction, and crossing the third source line;
a first semiconductor layer comprising a first crossing portion which crosses the first gate line and is located on a first source line side between the first source line and the second source line; and
a second semiconductor layer comprising a second crossing portion which crosses the second gate line and is located on a third source line side between the second source line and the third source line.

2. The display device of claim 1, wherein the first source line, the second source line and the third source line are arranged at regular intervals.

3. The display device of claim 1, wherein the first gate line and the second gate line are in line with each other.

4. The display device of claim 1, further comprising:
a first relay electrode located at an equal distance from the first source line and the second source line and connected to the first semiconductor layer; and
a second relay electrode located at an equal distance from the second source line and the third source line and connected to the second semiconductor layer.

5. The display device of claim 4, further comprising:
a first pixel electrode located between the first source line and the second source line and connected to the first relay electrode via a first contact hole; and
a second pixel electrode located between the second source line and the third source line and connected to the second relay electrode via a second contact hole, wherein
the first contact hole is formed at an equal distance from the first source line and the second source line, and
the second contact hole is formed at an equal distance from the second source line and the third source line.

6. The display device of claim 1, further comprising:
a first relay electrode located at different distances from the first source line and the second source line and connected to the first semiconductor layer; and
a second relay electrode located at different distances from the second source line and the third source line and connected to the second semiconductor layer.

7. The display device of claim 6, further comprising:
a first pixel electrode located between the first source line and the second source line and connected to the first relay electrode via a first contact hole; and
a second pixel electrode located between the second source line and the third source line and connected to the second relay electrode via a second contact hole, wherein
the first contact hole is formed at an equal distance from the first source line and the second source line, and
the second contact hole is formed at an equal distance from the second source line and the third source line.

8. The display device of claim 1, further comprising:
a first light-shielding layer extending along the first gate line and overlapping the first gate line; and
a second light-shielding layer extending along the second gate line, separated from the first light-shielding layer in the first direction, and overlapping the second gate line.

9. The display device of claim 1, wherein the first gate line and the second gate line do not cross the second source line.

10. The display device of claim 1, wherein the first gate line or the second gate line crosses the second source line.

11. The display device of claim 1, further comprising:
a third light-shielding layer extending along the first source line and overlapping the first source line;
a fourth light-shielding layer extending along the second source line and overlapping the second source line; and
a fifth light-shielding layer extending along the third source line and overlapping the third source line, wherein
the third light-shielding layer, the fourth light-shielding layer and the fifth light-shielding layer are arranged at regular intervals in the first direction and have a same width in the first direction.

12. The display device of claim 1, wherein the first gate line and the second gate line are deviated from each other in a second direction crossing the first direction.

13. A display device comprising:
a first source line, a second source line and a third source line arranged at regular intervals in a first direction;
a first gate line extending in the first direction and crossing the first source line;
a second gate line extending in the first direction, separated from the first gate line in the first direction, and crossing the third source line;
a first semiconductor layer comprising a first crossing portion which crosses the first gate line and is located between the first source line and the second source line; and
a second semiconductor layer comprising a second crossing portion which crosses the second gate line and is located between the second source line and the third source line.

14. The display device of claim 13, further comprising:
a first relay electrode located between the first source line and the second source line and electrically connected to the first semiconductor layer;
a second relay electrode located between the second source line and the third source line and electrically connected to the second semiconductor layer;
a first pixel electrode located between the first source line and the second source line and electrically connected to the first relay electrode via a first contact hole; and
a second pixel electrode located between the second source line the third source line and electrically connected to the second relay electrode via a second contact hole, wherein
the first contact hole is located at an equal distance from the first source line and the second source line, and
the second contact hole is located at an equal distance from the second source line and the third source line.

15. The display device of claim 14, wherein
the first gate line extends for a first distance from the first source line toward the second source line, and
the second gate line extends for a second distance different from the first distance from the third source line toward the second source line.

16. The display device of claim 15, wherein the first gate line crosses the second source line.

17. The display device of claim 16, wherein
the first crossing portion is located at an equal distance from the first source line and the second source line, and
the second crossing portion is located at different distances from the second source line and the third source line.

18. The display device of claim 14, wherein
the first gate line extends for a first distance from the first source line toward the second source line, and
the second gate line extends for a second distance different from the first distance from the third source line toward the second source line.

19. The display device of claim 18, wherein
the first crossing portion is located at different distances from the first source line and the second source line, and
the second crossing portion is located at different distances from the second source line and the third source line.

20. The display device of claim 19, wherein
the first crossing portion is located on a first source line side from the first contact hole, and
the second crossing portion is located on a third source line side from the second contact hole.
